(19) United States
(12) Patent Application Publication
(10) Pub. No.: US 2025/0318182 A1
(43) Pub. Date: Oct. 9, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kazusa ARIMA, Nomi Ishikawa (JP); Rie ARIMA, Nomi Ishikawa (JP); Hideharu KOJIMA, Kanazawa Ishikawa (JP); Hidenobu KOJIMA, Kanazawa Ishikawa (JP)

(21) Appl. No.: 18/825,973

(22) Filed: Sep. 5, 2024

(30) Foreign Application Priority Data
Apr. 5, 2024 (JP) 2024-061588

(51) Int. Cl. H01L 29/78; H01L 29/861

(52) U.S. Cl. CPC H10D 30/665; H10D 8/411

(57) ABSTRACT

A semiconductor device according to an embodiment includes: a semiconductor layer including a first principal surface, and a second principal surface on the opposite side from the first principal surface; a first conductive portion provided on the first principal surface of the semiconductor layer; a second conductive portion that is provided on the second principal surface of the semiconductor layer, and is joined to a metal piece via a joining material having conductivity, the joining material not being in contact with the first conductive portion; and a blocking portion that is provided on the first principal surface on the outer side of the first conductive portion, and is electrically insulated from the first conductive portion and the second conductive portion.

### CROSS-REFERENCE TO RELATED APPLICATIONS

This application is based upon and claims the benefit of priority from the prior Japanese Patent Application No.2024-061588, filed on Apr. 5, 2024; the entire contents of which are incorporated herein by reference.

### FIELD

Embodiments described herein relate generally to a semiconductor device.

### BACKGROUND

In a metal oxide semiconductor field effect transistor (MOSFET), a drift electrode is joined to a die pad via a conductive joining material such as solder. The source electrode and the drift electrode of the MOSFET are connected to different potentials during use, and a potential difference is generated between the source electrode and the drift electrode. Due to this potential difference, the joining material might flow toward the source electrode or a source wiring layer electrically connected to the source electrode. In a case where the joining material is in contact with the source electrode or the source wiring layer, short-circuiting might occur between the source electrode or the source wiring layer and the drift electrode via the joining material.

### BRIEF DESCRIPTION OF THE DRAWINGS

FIG. 1 is a plan view of a semiconductor device according to an embodiment;

FIG. 2 is a cross-sectional view taken along the line A-A defined in FIG. 1;

FIG. 3 is an enlarged cross-sectional view of a peripheral region in the semiconductor device according to the embodiment;

FIG. 4 is a cross-sectional view taken along the line A-A defined in FIG. 1, and is a view for explaining blocking of a joining material by a blocking portion;

FIG. 5A is a cross-sectional view for explaining an example of a process of manufacturing the semiconductor device according to the embodiment;

FIG. 5B is a cross-sectional view for explaining an example of a process of manufacturing the semiconductor device according to the embodiment, continuing from FIG. 5A;

FIG. 5C is a cross-sectional view for explaining an example of a process of manufacturing the semiconductor device according to the embodiment, continuing from FIG. 5B;

FIG. 5D is a cross-sectional view for explaining an example of a process of manufacturing the semiconductor device according to the embodiment, continuing from FIG. 5C;

FIG. 6 is a plan view of a semiconductor device according to Modification 1 of the embodiment;

FIG. 7 is a plan view of a semiconductor device according to Modification 2 of the embodiment;

FIG. 8 is a plan view of a semiconductor device according to Modification 3 of the embodiment;

FIG. 9 is an enlarged cross-sectional view of a peripheral region in a semiconductor device according to Modification 4 of the embodiment; and

FIG. 10 is an enlarged cross-sectional view of a peripheral region in a semiconductor device according to Modification 5 of the embodiment.

### DETAILED DESCRIPTION

A semiconductor device according to an embodiment includes: a semiconductor layer including a first principal surface, and a second principal surface on the opposite side from the first principal surface; a first conductive portion provided on the first principal surface of the semiconductor layer; a second conductive portion that is provided on the second principal surface of the semiconductor layer, and is joined to a metal piece via a joining material having conductivity, the joining material not being in contact with the first conductive portion; and a blocking portion that is provided on the first principal surface on the outer side of the first conductive portion, and is electrically insulated from the first conductive portion and the second conductive portion.

The following is a description of an embodiment of the present invention, with reference to the accompanying drawings. The embodiment does not limit the present invention. The drawings are schematic or conceptual, and the proportions and the like of the respective components are not necessarily the same as the actual ones. In the specification and the drawings, the same components as those already described with reference to the previously described drawings are denoted by the same reference numerals as those used in the previously described drawings, and detailed explanation thereof will not be unnecessarily repeated.

Further, for ease of explanation, in the stacking direction (thickness direction) of a semiconductor device, the source electrode side will be also referred to as the “upper” side, and the drain electrode side will be also referred to as the “lower” side. However, this expression is used only for convenience, and is independent of the direction of gravity.

Also, in the description below, notations n⁺, n, and n⁻, and p⁺, p, and p⁻ will be used in some cases to express the relative level of impurity concentration in each conductivity type. Specifically, n⁺ indicates that the n-type impurity concentration is relatively higher than n, and n indicates that the n-type impurity concentration is relatively lower than n. Also, p⁺ indicates that the p-type impurity concentration is relatively higher than p, and p⁻ indicates that the p-type impurity concentration is relatively lower than p. In a case where both the p-type impurity and the n-type impurity are contained in each region, these notations indicate the relative level of the net impurity concentration after the impurities have compensated for each other. Note that, in the description below, the n-type and the p-type may be reversed.

The impurity concentration of a semiconductor region can be measured by secondary ion mass spectrometry (SIMS), for example. The relative level of impurity concentration can also be determined from the level of carrier concentration obtained by Scanning Capacitance Microscopy (SCM), for example.

Dimensions such as the width of the blocking portion can be measured by analysis of a surface and/or a cross section with a transmission electron microscope (TEM), energy dispersive X-ray spectroscopy (EDX), or a scanning electron microscope (SEM), for example.

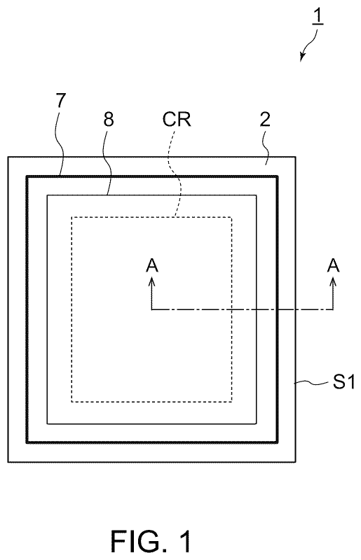

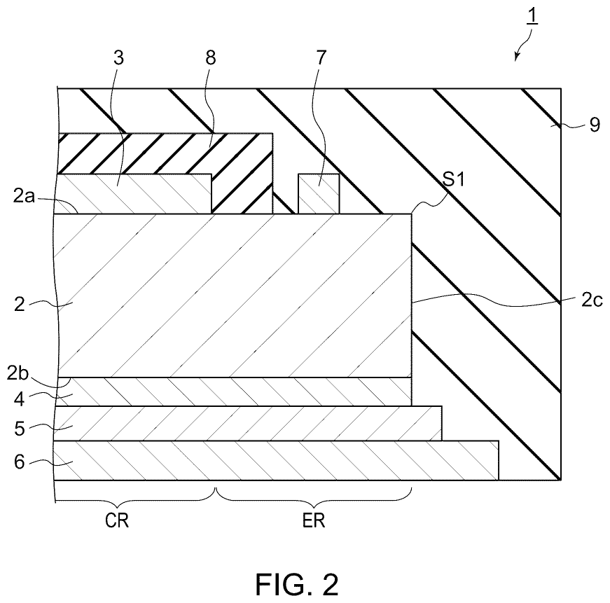

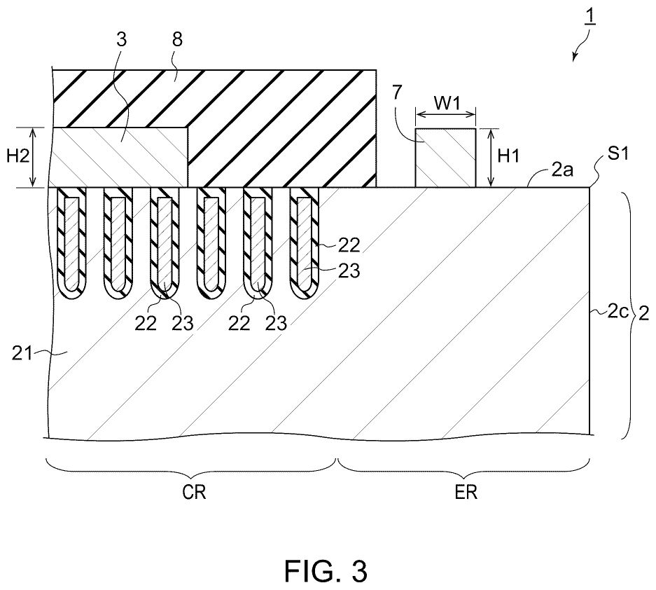

Referring now to FIGS. 1 to 3, a semiconductor device 1 according to an embodiment is described. FIG. 1 is a plan view of the semiconductor device 1 according to the present embodiment. FIG. 2 is a cross-sectional view of the semiconductor device 1 according to the present embodiment, taken along the line A-A defined in FIG. 1. FIG. 3 is an enlarged cross-sectional view of a peripheral region ER in the semiconductor device 1 according to the present embodiment.

The semiconductor device 1 is a vertical transistor such as a diode, a bipolar transistor, a MOSFET, or an insulated gate bipolar transistor (IGBT), for example. In the description below, a case where the semiconductor device 1 is a vertical MOSFET will be explained as an example.

As illustrated in FIGS. 1 and 2, the semiconductor device 1 according to the present embodiment includes a semiconductor layer 2, a source wiring layer 3, a drain electrode 4, a joining material 5, a die pad 6, a blocking portion 7, an insulating protection portion 8, and a sealing portion 9. Note that, in FIG. 1, the sealing portion 9 is not illustrated.

In the semiconductor layer 2, a drift region 21 and the like described later are provided. The semiconductor layer 2 may be an epitaxial layer, a semiconductor substrate, or a semiconductor substrate and an epitaxial layer disposed on the semiconductor substrate. In the present embodiment, the semiconductor layer 2 is a silicon (Si) layer. In this case, arsenic (As), phosphorus (P), or antimony (Sb) is used as the n-type impurity, and boron (B) is used as the p-type impurity, for example. Note that the material of the semiconductor layer 2 is not limited to any particular kind. The semiconductor layer 2 may be formed with a compound semiconductor such as silicon carbide (SiC) or gallium nitride (GaN).

As illustrated in FIG. 2, the semiconductor layer 2 includes an upper surface (first principal surface) 2a, a lower surface (second principal surface) 2b on the opposite side from the upper surface 2a, and a side surface 2c that is a dicing surface. The source wiring layer 3 is provided on the upper surface 2a of the semiconductor layer 2, and the drain electrode 4 is provided on the lower surface 2b of the semiconductor layer 2.

The source wiring layer 3 is a wiring layer electrically connected to a source electrode (not illustrated) of the MOSFET. In the present embodiment, the source wiring layer 3 is a wiring layer electrically connected to the source electrode of the MOSFET, and is located at an end portion (terminal) on the upper surface 2a of the semiconductor layer 2. The source wiring layer 3 is formed with aluminum (Al), copper (Cu), titanium (Ti), tungsten (W), or the like, for example. The source wiring layer 3 is an example of the first conductive portion in the claims.

The drain electrode 4 functions as a drain electrode of the MOSFET. When the semiconductor device 1 is used, the drain electrode 4 is connected to a potential different from that of the source wiring layer 3. That is, when the semiconductor device 1 is used, a potential difference is generated between the source wiring layer 3 and the drain electrode 4. The drain electrode 4 is formed with aluminum (Al), copper (Cu), titanium (Ti), tungsten (W), or the like, for example. The drain electrode 4 is an example of the second conductive portion in the claims.

Next, an example of the internal configuration of the semiconductor layer 2 is described.

As illustrated in FIGS. 2 and 3, the semiconductor layer 2 includes a cell region (current region) CR and a peripheral region (termination region) ER.

The cell region CR is a region connected to the source wiring layer 3 and the drain electrode 4, and current flows between the source wiring layer 3 and the drain electrode 4 in the region. That is, the cell region CR is electrically connected to the source wiring layer 3 and the drain electrode 4. As illustrated in FIG. 3, a drift region 21, insulating regions 22, and field plate electrodes (FP electrodes) 23 are provided in the cell region CR.

The drift region 21 functions as a drift region of the MOSFET. The drift region 21 is an n-type semiconductor region, for example. The n-type impurity concentration in the drift region 21 is 1×10¹⁵ cm⁻³ or higher, but is not higher than 2×10¹⁶ cm⁻³, for example.

The insulating regions 22 are insulating films that cover the sidewalls of trenches formed in the upper surface 2a of the semiconductor layer 2. The insulating regions 22 contain silicon oxide or silicon nitride, for example.

The FP electrodes 23 are provided in semiconductor layer 2 via the insulating regions 22. The FP electrodes 23 are formed with polysilicon containing p-type or n-type impurity, for example. The FP electrodes 23 are electrically connected to the source electrode. As such FP electrodes 23 are provided, concentration of a reverse electric field between the source wiring layer 3 and the drain electrode 4 is alleviated, and the withstand voltage of the semiconductor device 1 is increased.

Although not illustrated in the drawings, n-type semiconductor regions such as a drain region and a source region, a p-type semiconductor region such as a base region, and the like are provided in the cell region CR. Further, in the present embodiment, the source wiring layer 3 is provided on the cell region CR.

The peripheral region ER is a region provided around the cell region CR. The peripheral region ER is located between the cell region CR and the side surface 2c of the semiconductor layer 2. The peripheral region ER is electrically insulated from the cell region CR. That is, when current flows in the cell region CR, the current does not flow into the peripheral region ER.

Note that the internal configuration of the semiconductor layer 2 illustrated in FIG. 3 is merely an example, and the present embodiment is not limited to this. For example, in the example illustrated in FIG. 3, six FP electrodes 23 are provided. The present embodiment is not limited to this, and the number of FP electrodes 23 may be more or less than six, or may not be provided at all.

As illustrated in FIG. 2, the drain electrode 4 is bonded to a metal piece such as the die pad 6, which is part of a lead frame, via the joining material 5. The joining material 5 is a joining material having conductivity, such as solder or a conductive paste.

The blocking portion 7 is provided on the upper surface 2a on the outer side (the dicing surface side, which is the side of the side surface 2c) of the source wiring layer 3 so as to be separated from the source wiring layer 3. More specifically, as illustrated in FIG. 3, the blocking portion 7 is provided on the upper surface 2a of the semiconductor layer 2 at a position closer to a side portion S1 of the upper surface 2a than to the source wiring layer 3. In the present embodiment, the blocking portion 7 is provided on the portion of the upper surface 2a exposed without being covered with the insulating protection portion 8 in the peripheral region ER. As illustrated in FIG. 3, the height H1 of the blocking portion 7 is equal to the height H2 of the source wiring layer 3.

In the present embodiment, the blocking portion 7 is formed with a conductive material such as a metal material. The metal material may be a material that does not form a passive state, and binds to the joining material 5. Such a metal material contains at least one of copper, titanium, tungsten, and platinum, for example. With this arrangement, the joining material 5 is attracted to the blocking portion 7, and the effect of blocking contact of the joining material 5 with the source wiring layer 3 (this effect will be hereinafter referred to as the “blocking effect”) can be enhanced.

Alternatively, in a case where the blocking portion 7 includes a metal material, the metal material may be a material that forms a passive state and repels the joining material 5. Such a metal material contains at least one of aluminum, nickel, iron, chromium, and cobalt, for example. With this arrangement, the joining material 5 5 is bounced back by the blocking portion 7, and the blocking effect of the blocking portion 7 can be enhanced.

Alternatively, the blocking portion 7 may be formed with the same material as the source wiring layer 3. With this arrangement, the blocking portion 7 can be formed at the same time as the source wiring layer 3. Note that the blocking portion 7 may contain an insulating material having a higher strength than that of the material of the insulating protection portion 8.

The blocking portion 7 is electrically insulated from the source wiring layer 3, the drain electrode 4, and other wiring lines, electrodes, and the like in the semiconductor device 1. The blocking portion 7 is designed to block contact of the joining material 5 with the source wiring layer 3. That is, the blocking portion 7 blocks the joining material 5 from coming into contact with the source wiring layer 3.

The insulating protection portion 8 is provided to protect the source wiring layer 3. The insulating protection portion 8 is provided on the upper surface 2a of the semiconductor layer 2, and covers the source wiring layer 3. The insulating protection portion 8 is polyimide, for example.

In the present embodiment, the insulating protection portion 8 does not cover the blocking portion 7. That is, the blocking portion 7 is provided at a distance from the insulating protection portion 8. Note that, in the present embodiment, the portion of the upper surface 2a of the semiconductor layer 2 that is not covered with the insulating protection portion 8 serves as a dicing line when the semiconductor device 1 is manufactured. The blocking portion 7 is provided on the dicing line.

As illustrated in FIG. 2, the sealing portion 9 seals the semiconductor layer 2, the source wiring layer 3, the drain electrode 4, the joining material 5, the die pad 6, the blocking portion 7, and the insulating protection portion 8. The sealing portion 9 is formed with epoxy resin, for example. Note that, in FIG. 2, the sealing portion 9 does not cover the lower surface of the die pad 6 on the opposite side from the joining material 5. The present embodiment is not limited to this, and the sealing portion 9 may cover the lower surface of the die pad 6.

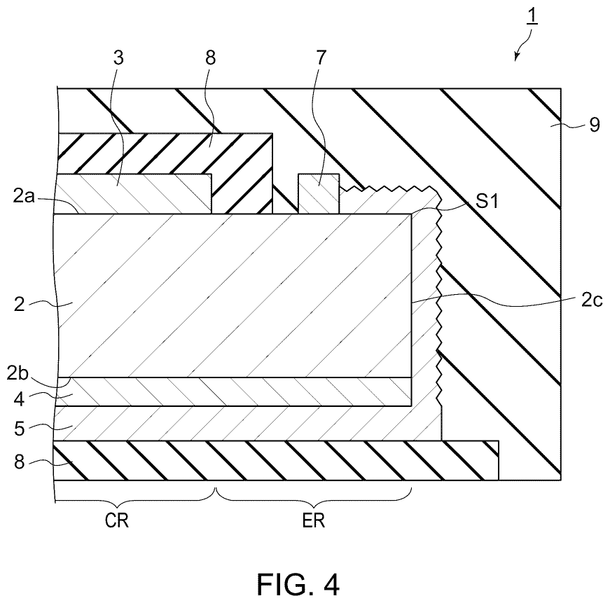

Here, blocking of the joining material 5 by the blocking portion 7 is described with reference to FIG. 4. FIG. 4 is a cross-sectional view of the semiconductor device 1 according to the present embodiment during operation, taken along the line A-A defined in FIG. 1.

As illustrated in FIG. 4, during use of the semiconductor device 1, the joining material 5 gradually flows from the drain electrode 4 toward the source wiring layer 3, due to a potential difference between the source wiring layer 3 and the drain electrode 4. In the example illustrated in FIG. 4, the joining material 5 crawls up to the upper surface 2a of the semiconductor layer 2 along the side surface 2c of the semiconductor layer 2, and flows toward the source wiring layer 3. However, as illustrated in FIG. 4, the blocking portion 7 blocks the joining material 5, so that the joining material 5 is prevented from coming into contact with the source wiring layer 3. That is, in the present embodiment, the joining material 5 is not in contact with the source wiring layer 3, even when the semiconductor device 1 is being used.

As described above, the semiconductor device 1 according to the present embodiment includes: the semiconductor layer 2 including the upper surface 2a and the lower surface 2b; the source wiring layer 3 provided on the upper surface 2a of the semiconductor layer 2; the drain electrode 4 that is provided on the lower surface 2b of the semiconductor layer 2 and is joined to the die pad 6 via the joining material 5 having conductivity; and the blocking portion 7 that is provided on the upper surface 2a on the outer side of the source wiring layer 3, is electrically insulated from the source wiring layer 3 and the drain electrode 4, and blocks the joining material 5 from coming into contact with the source wiring layer 3.

As described above, in the present embodiment, the blocking portion 7 that blocks contact of the joining material 5 with the source wiring layer 3 when the joining material 5 flows toward the source wiring layer 3 due to a potential difference generated between the source wiring layer 3 and the drain electrode 4 during the use of the semiconductor device 1 is provided. Thus, according to the present embodiment, it is possible to prevent short-circuiting between the source wiring layer 3 and the drain electrode 4 via the joining material 5. As a result, the reliability of the semiconductor device 1 can be increased.

Note that, in the present embodiment, the source wiring layer 3 is provided on the cell region CR, and the blocking portion 7 is provided on the peripheral region ER. The present embodiment is not limited to this, and the source wiring layer 3 may be provided in the peripheral region ER, as long as the source wiring layer 3 is provided on the inner side of the blocking portion 7 (the opposite side from the dicing surface). Alternatively, the blocking portion 7 may be provided on the cell region CR, as long as the blocking portion 7 is provided on the outer side of the source wiring layer 3 and is electrically insulated from the cell region CR by an interlayer insulating film or the like.

Further, as illustrated in FIG. 1, the semiconductor layer 2 according to the present embodiment has a rectangular planar shape, and the blocking portion 7 is provided on the upper surface 2a of the semiconductor layer 2 so as to surround the source wiring layer 3 provided on the cell region CR. In other words, the blocking portion 7 of the present embodiment forms a closed curve surrounding the source wiring layer 3 on the upper surface 2a of the semiconductor layer 2. Note that the semiconductor layer 2 may have a planar shape that is not rectangular, such as a circular shape or a polygonal shape. In such a case, the blocking portion 7 may have a shape conforming to the shape of a side portion of the semiconductor device 1.

Furthermore, in the present embodiment, the height H1 of the blocking portion 7 is equal to the height H2 of the source wiring layer 3, as described above. The present embodiment is not limited to this, and the height H1 and the width W1 of the blocking portion 7 may be set as appropriate. For example, the width W1 of the blocking portion 7 may be equal to or greater than the height H1 of the blocking portion 7. With this arrangement, the strength of the blocking portion 7 and the processing stability at the time of manufacturing of the semiconductor device 1 become higher, and the reliability of the semiconductor device 1 can be increased.

### Method for Manufacturing the Semiconductor Device 1

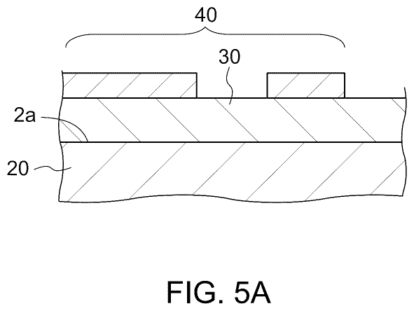

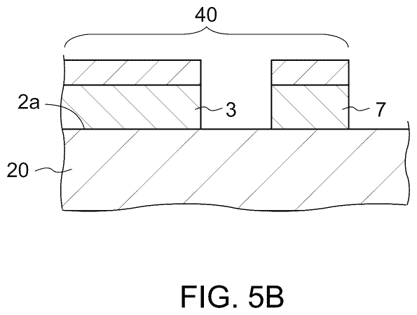

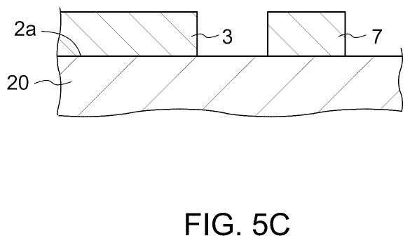

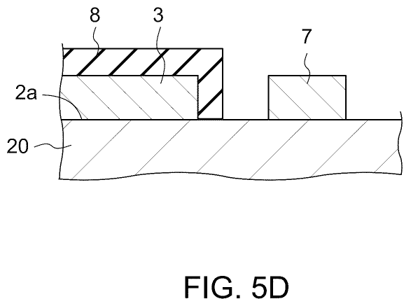

Referring next to FIGS. 5A to 5D, an example of a method for manufacturing the semiconductor device 1 is described. FIGS. 5A to 5D are cross-sectional views for explaining an example of a process of manufacturing a semiconductor device according to the present embodiment.

First, as illustrated in FIG. 5A, a semiconductor member that includes a semiconductor wafer 20, a conductive layer 30 provided on the upper surface 2a of the semiconductor wafer 20, and a resist pattern 40 provided on the conductive layer 30 is prepared.

Such a semiconductor member is obtained in the manner described below, for example. First, the semiconductor wafer 20 is prepared. In the semiconductor wafer 20, the drift region 21, the insulating regions 22, the FP electrodes 23, and the like are provided. Next, the conductive layer 30 is formed on the upper surface 2a of the semiconductor wafer 20. The conductive layer 30 is formed by depositing aluminum on the upper surface 2a by sputtering, for example. After that, a resist is applied onto the conductive layer 30, to form a resist film. The resist film is then subjected to patterning by photolithography or the like, to form the resist pattern 40. Thus, the semiconductor member illustrated in FIG. 5A is obtained.

Next, as illustrated in FIG. 5B, the conductive layer 30 not covered with the resist pattern 40 is removed by wet etching, isotropic or anisotropic etching such as reactive ion etching (RIE), or the like. Thus, patterning is performed on the conductive layer 30, and the source wiring layer 3 and the blocking portion 7 are formed. In this example, the blocking portion 7 is formed on the dicing line.

Next, as illustrated in FIG. 5C, the resist pattern 40 is removed.

Next, as illustrated in FIG. 5D, an insulating material such as polyimide is applied, to form the insulating protection portion 8 covering the source wiring layer 3. For example, after polyimide is applied onto the entire upper surface 2a and is cured, the cured insulating material (cured insulating film) covering the blocking portion 7 is removed by photolithography.

After that, the drain electrode 4 is formed on the lower surface of the semiconductor wafer, though not illustrated in the drawing. Dicing is then performed on the semiconductor wafer 20 so that the blocking portion 7 remains.

After that, the drain electrode 4 is joined to the die pad 6 via the joining material 5, and is sealed with the sealing portion 9. Through the above steps, the semiconductor device 1 is manufactured.

By the manufacturing method according to the present embodiment, the source wiring layer 3 and the blocking portion 7 can be collectively formed. Thus, the semiconductor device 1 including the blocking portion 7 can be easily manufactured at low cost.

In the description below, modifications according to the present embodiment are explained. The same effects as those of the present embodiment can be achieved with any of the modifications.

### Modification 1

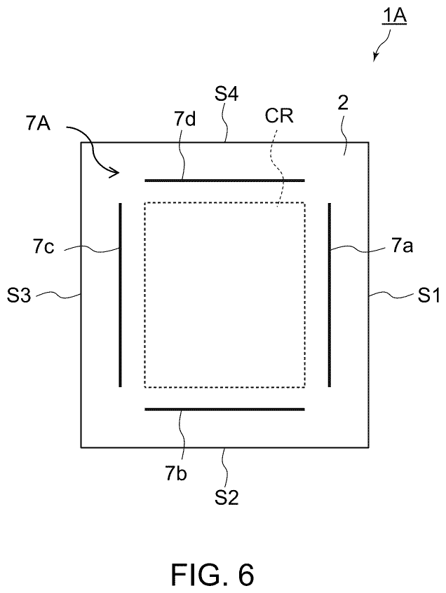

Referring now to FIG. 6, a semiconductor device 1A according to Modification 1 of the embodiment is described. FIG. 6 is a plan view of the semiconductor device 1A according to the present modification. Note that, in FIG. 6, the source wiring layer 3, the insulating protection portion 8, and the sealing portion 9 are not shown. One of the differences between the above embodiment and the present modification lies in the planar shape of the blocking portion.

As illustrated in FIG. 6, a blocking portion 7A of the present modification is not provided at the corner portions of the semiconductor layer 2, unlike the blocking portion 7 of the embodiment. In the example illustrated in FIG. 6, the semiconductor layer 2 has a rectangular planar shape, and the blocking portion 7A is not provided on the lines connecting the center of the upper surface 2a (the center of the cell region CR) and the four corner portions of the upper surface 2a. More specifically, the blocking portion 7A includes a blocking portion 7a provided between the cell region CR and the side portion S1 on the upper surface 2a, a blocking portion 7b provided between the cell region CR and a side portion S2, a blocking portion 7c provided between the cell region CR and a side portion S3, and a blocking portion 7d provided between the cell region CR and a side portion S4. In addition, the blocking portions 7a to 7d each block the joining material 5 that crawls up from each of the side portions S1 to S4 and flows toward the source wiring layer 3. In the example illustrated in FIG. 6, the blocking portions 7a and 7c are equal to the length of the source wiring layer 3 in the longitudinal direction in the drawing, and the blocking portions 7b and 7d are equal to the length of the source wiring layer 3 in the lateral direction in the drawing. The present modification is not limited to this, and the blocking portion 7A may be not provided on at least a line connecting the center of the upper surface 2a and at least a corner portion of the upper surface 2a.

In a case where the joining material 5 flows toward the source wiring layer 3 due to a potential difference generated between the source wiring layer 3 and the drain electrode 4, the joining material 5 is more likely to flow into the upper surface 2a through the side portions S1 to S4 of the semiconductor layer 2, than through the corner portion of the semiconductor layer 2. Therefore, it is less necessary to provide the blocking portion 7A at the corner portions of the semiconductor layer 2 than at the side portions S1 to S4 of the semiconductor layer 2.

According to the present modification, the degree of freedom in designing the blocking portion 7A can be increased.

Note that the semiconductor layer 2 may have a planar shape that is not rectangular, such as a polygonal shape. In such a case, the blocking portion 7A may be formed with the same number of blocking portions as the number of the side portions of the semiconductor device 1.

### Modification 2

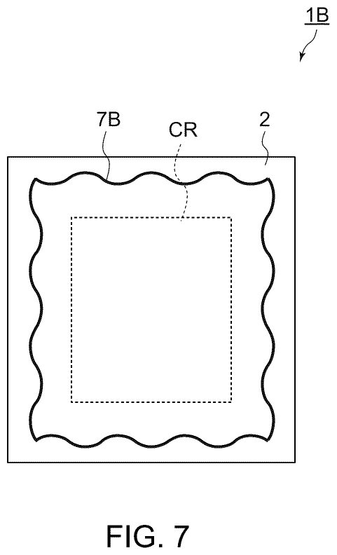

Referring next to FIG. 7, a semiconductor device 1B according to Modification 2 of the embodiment is described. FIG. 7 is a plan view of the semiconductor device 1B according to Modification 2 of the embodiment. Note that, in FIG. 7, the source wiring layer 3, the insulating protection portion 8, and the sealing portion 9 are not shown. One of the differences between the above embodiment and the present modification lies in the planar shape of the blocking portion.

As illustrated in FIG. 7, the blocking portion 7B of the present modification has a planar shape that is bent in the upper surface 2a of the semiconductor layer 2. As described above, the blocking portion 7B may have a plurality of curved and/or linear portions.

According to the present modification, the area of the side surfaces of the blocking portion is larger, and a larger area of the blocking portion 7B faces the joining material 5 crawling up onto the upper surface 2a of the semiconductor layer 2. Thus, the blocking effect of the blocking portion 7B can be enhanced. Note that, in a case where the blocking portion 7B does not form a passive state, or includes a metal material that forms a passive state, the blocking portion 7B more strongly binds to or repels the joining material 5, and thus, the blocking effect can be further enhanced.

### Modification 3

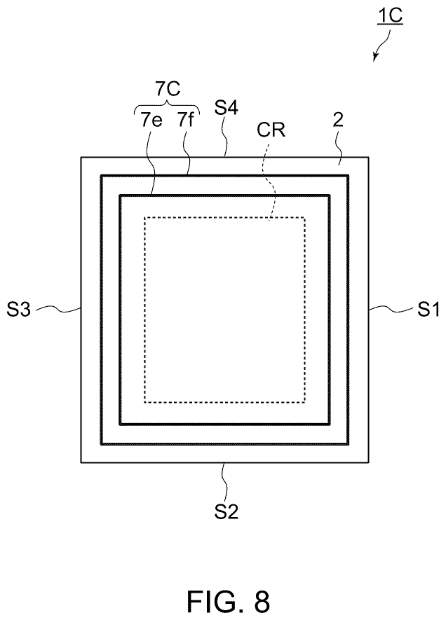

Referring next to FIG. 8, a semiconductor device 1C according to Modification 3 of the embodiment is described. FIG. 8 is a plan view of the semiconductor device 1C according to Modification 3 of the embodiment. Note that, in FIG. 8, the source wiring layer 3, the insulating protection portion 8, and the sealing portion 9 are not shown. One of the differences between the above embodiment and the present modification lies in the number of blocking portions.

As illustrated in FIG. 8, the blocking portion 7C according to the present modification includes a blocking portion 7e (an inner blocking portion) surrounding the cell region CR or surrounding the source wiring layer 3, and a blocking portion 7f (an outer blocking portion) surrounding the blocking portion 7e. As described above, in the present modification, a plurality of blocking portions 7e and 7f is provided between the source wiring layer 3 and the side portions S1 to S4 of the semiconductor layer 2, on the upper surface 2a (the principal surface) of the semiconductor layer 2. Thus, the blocking effect of the blocking portion 7C can be enhanced.

Note that, in the example illustrated in FIG. 8, the plurality of blocking portions 7e and 7f is provided between the source wiring layer 3 and all the side portions among the side portions S1 to S4 of the semiconductor layer 2, on the upper surface 2a (the principal surface) of the semiconductor layer 2. The present modification is not limited to this, and, on the upper surface 2a of the semiconductor layer 2, the plurality of blocking portions 7e and 7f may be provided between the source wiring layer 3 and at least one of the side portions S1 to S4 of the semiconductor layer 2.

In the example illustrated in FIG. 8, two blocking portions 7e and 7f are provided. The present modification is not limited to this, and a blocking portion (not illustrated) surrounding the blocking portion 7f may be further provided. More generally, three or more blocking portions may be provided between the source wiring layer 3 and at least one of the side portions S1 to S4 of the semiconductor layer 2, depending on the distance between the source wiring layer 3 and the side portions S1 to S4.

Furthermore, the planar shape of the blocking portion 7C of the present modification is not limited to any particular shape. For example, in the blocking portion 7C, a notch may be formed only between the inner blocking portion 7e and the side portion S1, and a notch may be formed only between the outer blocking portion 7d and the side portion S3. With such a shape, the flow channel of the joining material 5 from the drain electrode 4 to the source wiring layer 3 becomes longer, and the blocking effect of the blocking portion 7C can be enhanced.

Further, the plurality of blocking portions 7e and 7f included in the blocking portion 7C may contain different materials from each other. For example, the blocking portion 7e may contain a metal material that binds to the joining material 5, and the blocking portion 7f may contain a metal material that repels the joining material 5. Conversely, the blocking portion 7e may contain a metal material that repels the joining material 5, and the blocking portion 7f may contain a metal material that binds to the joining material 5. With this arrangement, different characteristics are combined, and the blocking effect of the blocking portion 7C can be enhanced.

### Modification 4

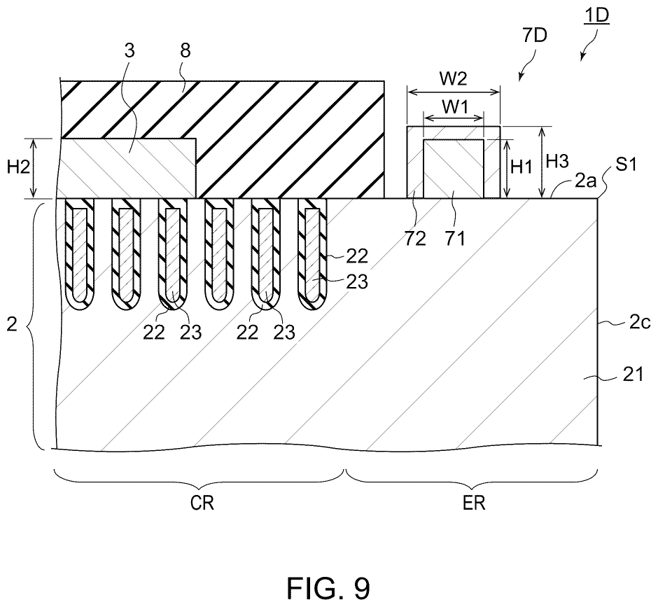

Referring next to FIG. 9, a semiconductor device 1D according to Modification 4 of the embodiment is described. FIG. 9 is an enlarged cross-sectional view of the peripheral region ER in the semiconductor device 1D according to Modification 4 of the embodiment. One of the differences between the above embodiment and the present modification lies in that the blocking portion is placed.

As illustrated in FIG. 9, a blocking portion 7D according to the present modification includes a main body portion 71 that is in contact with the upper surface 2a of the semiconductor layer 2 at the bottom surface, and a plating portion 72 that covers the side surfaces and the upper surface of the main body portion 71. The main body portion 71 corresponds to the blocking portion 7 according to the embodiment. The height H3 of the blocking portion 7D including the main body portion 71 and the plating portion 72 is greater than the height H2 of the source wiring layer 3. Also, the width W2 of the blocking portion 7D including the main body portion 71 and the plating portion 72 is greater than the width W1 of the main body portion 71. Thus, the blocking effect of the blocking portion 7D can be enhanced.

Note that the main body portion 71 may be formed with the same material as the source wiring layer 3. With this arrangement, the main body portion 71 can be formed at the same time as the source wiring layer 3.

Further, the plating portion 72 may be formed with the same material as or a different material from the main body portion 71. In a case where the plating portion 72 is formed with a different material from that of the main body portion 71, when the main body portion 71 is formed at the same time as the source wiring layer 3, for example, the metal material for the surface of the blocking portion 7D can be more freely selected. Furthermore, the plating portion 72 may be formed with a material having characteristics different from those of the main body portion 71. For example, the main body portion 71 may be formed with a metal material that binds to the joining material 5, and the plating portion 72 may be formed with a metal material that repels the joining material 5. Conversely, the main body portion 71 may be formed with a metal material that repels the joining material 5, and the plating portion 72 may be formed with a metal material that binds to the joining material 5.

### Modification 5

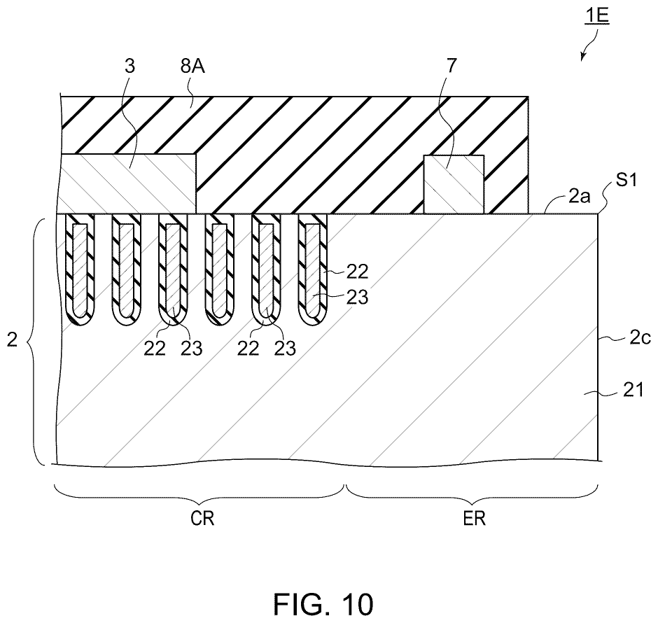

Referring next to FIG. 10, a semiconductor device 1E according to Modification 5 of the embodiment is described. FIG. 10 is an enlarged cross-sectional view of the peripheral region ER in the semiconductor device 1E according to Modification 5 of the embodiment. One of the differences between the above embodiment and the present modification lies in that the blocking portion 7 is covered with an insulating protection portion 8A.

As illustrated in FIG. 10, the blocking portion 7 of the present modification is covered with the insulating protection portion 8A provided on the upper surface 2a of the semiconductor layer 2.

With this arrangement, the photolithography process for the insulating protection portion becomes unnecessary, and the semiconductor device 1E can be easily manufactured. Furthermore, at the time of sealing by the sealing portion 9, the blocking portion 7 can be protected.

Note that, in the example illustrated in FIG. 10, the entire blocking portion 7 is covered with the insulating protection portion 8A. The present modification is not limited to this, and part of the blocking portion 7 may not be covered with the insulating protection portion 8A.

The embodiment and the modifications have been described so far. In the above embodiment and each modification, the source wiring layer 3 is the first conductive portion in the claims, and the drain electrode 4 is the second conductive portion in the claims. The first conductive portion and the second conductive portion are not limited to them, as long as the first conductive portion and the second conductive portion are connected to different potentials during an operation of the semiconductor device 1. For example, the first conductive portion in the claims may be a source electrode disposed at an end portion (terminal) of the semiconductor device 1, or another conductive portion such as a source pad that is electrically connected to the source electrode and is located at an end portion of the semiconductor device 1. As another example, the first conductive portion in the claims may be a gate electrode disposed at an end portion of the semiconductor device 1, or another conductive portion such as a gate wiring layer or a gate pad that is electrically connected to the gate electrode and is located at an end portion of the semiconductor device 1, for example. As yet another example, the first conductive portion may be a drain electrode disposed at an end portion of the semiconductor device 1, or another conductive portion electrically connected to the drain electrode, and the second conductive portion may be a source electrode, a gate electrode, or the like. In these examples, the blocking portion blocks the joining material from coming into contact with the source electrode, the source pad, the gate wiring layer, the gate electrode, the gate pad, the drain electrode, or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer including a first principal surface, and a second principal surface on an opposite side from the first principal surface;
a first conductive portion provided on the first principal surface of the semiconductor layer;
a second conductive portion that is provided on the second principal surface of the semiconductor layer, and is joined to a metal piece via a joining material having conductivity, the joining material not being in contact with the first conductive portion; and
a blocking portion that is provided on the first principal surface on an outer side of the first conductive portion, and is electrically insulated from the first conductive portion and the second conductive portion.

2. The semiconductor device according to claim 1, wherein the blocking portion blocks the joining material from coming into contact with the first conductive portion.

3. The semiconductor device according to claim 1, further comprising:
a current region that is provided in the semiconductor layer, is connected to the first conductive portion and the second conductive portion, and has a current flowing between the first conductive portion and the second conductive portion; and
a peripheral region that is provided around the current region in the semiconductor layer, and is electrically insulated from the current region, wherein
the blocking portion is provided on the first principal surface in the peripheral region.

4. The semiconductor device according to claim 1, wherein the blocking portion is provided to surround the first conductive portion.

5. The semiconductor device according to claim 4, wherein
the semiconductor layer has a rectangular planar shape, and
the blocking portion is not provided on a line connecting a center of the first principal surface and a corner portion of the first principal surface.

6. The semiconductor device according to claim 1, wherein the blocking portion has a bent planar shape.

7. The semiconductor device according to claim 1, wherein a plurality of the blocking portions is provided between the first conductive portion and a side portion of the semiconductor layer.

8. The semiconductor device according to claim 1, wherein the blocking portion includes a main body portion that is formed with the same material as the first conductive portion and is in contact with the first principal surface.

9. The semiconductor device according to claim 8, wherein the blocking portion further includes a plating portion that covers the main body portion and is formed with a material different from the first conductive portion.

10. The semiconductor device according to claim 1, wherein the blocking portion includes a main body portion that is in contact with the first principal surface, and a plating portion that covers the main body portion.

11. The semiconductor device according to claim 10, further comprising an insulating protection portion that covers the first conductive portion, wherein
the blocking portion is provided at a distance from the insulating protection portion.

12. The semiconductor device according to claim 1, wherein the blocking portion contains a metal material.

13. The semiconductor device according to claim 12, wherein the metal material of the blocking portion is a material that binds to the joining material.

14. The semiconductor device according to claim 13, wherein the metal material of the blocking portion contains at least one of copper, titanium, tungsten, or platinum.

15. The semiconductor device according to claim 12, wherein the metal material of the blocking portion is a material that repels the joining material.

16. The semiconductor device according to claim 15, wherein the metal material of the blocking portion contains at least one of aluminum, nickel, iron, chromium, or cobalt.

17. The semiconductor device according to claim 1, further comprising an insulating protection portion that covers the first conductive portion, wherein
the blocking portion is covered with the insulating protection portion.

18. The semiconductor device according to claim 1, wherein a width of the blocking portion is equal to or greater than a height of the blocking portion.

19. The semiconductor device according to claim 1, further comprising a sealing portion that seals the semiconductor layer, the second conductive portion, the blocking portion, and the metal piece.

20. The semiconductor device according to claim 1, wherein the semiconductor device is one of a diode or a transistor.
